(19) United States
(12) Patent Application Publication
(10) Pub. No.: US 2002/0119618 A1
(43) Pub. Date: Aug. 29, 2002

(54) Method for forming contacts of memory devices using an etch stop layer

(75) Inventors: Uway Tseng, Taichung (TW); Kent Kuohua Chang, Taipei (TW); Pei-Hung Chu, Hsinchu (TW); Wen-Pin Lu, Yilan Hsien (TW)

Correspondence Address: LOWE HAUPTMAN GOPSTEIN, GILMAN & BERNER, LLP, 1700 Diagonal Road, Suite 310, Alexandria, VA, 22314, US

(73) Assignee: MACRONIX INTERNATIONAL CO., LTD.

(21) Appl. No.: 09/794,027

(22) Filed: Feb. 28, 2001

(51) Int. Cl. H01L 21/8242

(52) U.S. Cl. 438/241

(57) ABSTRACT

A method for forming a plurality of contact openings on a semiconductor substrate using an etch stop layer is disclosed herein. A semiconductor substrate is provided having a plurality of memory devices and a plurality of isolation regions formed thereon. A silicon oxide layer is formed on the plurality of semiconductor devices, the plurality of isolation regions, and the semiconductor substrate. An etch stop layer is formed on the silicon oxide layer followed by depositing a thick interlevel dielectric layer. A photoresist layer is pattern on the interlevel dielectric layer to define contact regions. A first dry etching process is performed to create a plurality of contact openings with different dimension in the interlevel dielectric layer until exposing portions of the etch stop layer. A second dry etching process is performed to create the plurality of contact openings through the etch stop layer. A third dry etching process is then performed to create the plurality of contact openings through the silicon oxide layer, exposing portions of the active regions of the plurality of memory devices. The pattern photoresist layer is then removed.

### BACKGROUND OF THE INVENTION

1. Field of the Invention

The present invention relates to a method for forming memory devices, and more specifically to a method for forming contacts of memory devices using an etch stop layer.

2. Description of the Prior Art

The semiconductor industry is continually striving to reduce the processing cost of a specific semiconductor chip, by reducing the size of the chip, while still maintaining, or increasing the device density of that specific semiconductor chip. The attainment of additional chips, from a specific size starting semiconductor substrate, reduces the processing cost of a specific chip. The attainment of smaller semiconductor chips has been in part a result of micro-miniaturization, or the ability to fabricate semiconductor chips using sub-micron features. Micro-miniaturization has been accomplished via advancements in specific semiconductor fabrication procedures, such as photolithography and reactive ion etching. The development of advanced dry etching tools and processes, have allowed the sub-micron images, in masking photoresist layers, to be transferred to underlying materials, such a silicon oxide, silicon nitride, and polysilicon, creating these materials, with sub-micron features, this resulting in smaller semiconductor chips, still possessing higher device densities.

The ability to use sub-micron features, or micro-miniaturization, has allowed performance improvements to be realized by the reduction of resistance and parasitic capacitance, resulting from the use of smaller features. In addition, the use of sub-micron features, results in smaller silicon chips with increased circuit densities, thus allowing more silicon chips to be obtained from a starting silicon substrate, thus reducing the cost of an individual silicon chip.

When constructing a memory cell using a semiconductor substrate, metal contacts must be provided to each layer formed on the substrate. For example, a metal-oxide-semiconductor transistor formed on the semiconductor substrate has a gate region, a source region, and a drain region. A metal contact must be provided to each of these regions, so that the appropriate voltage and/or current can be supplied to the gate, source and drain of the MOS transistor. Given the small size of such memory devices, there is not much leeway in providing such contacts, and any errors in this process may lead to defective components.

Additionally, as the step height of topography is too large for the ultra large-scale semiconductor device, the contact of the periphery circuit is widely used. As shown in FIGS. 1 and 2, a plurality of contact openings is formed in the semiconductor device mentioned above. The silicon substrate 2 is provided for the semiconductor device mentioned above and has a plurality of isolation regions 4 and a plurality of semiconductor devices 8 formed thereon, comprising array region 6 and periphery region. The semiconductor devices are formed of gate structures, dielectric spacers, and active regions. A first dielectric layer 10 and a second dielectric layer 12 are subsequently deposited on the semiconductor substrate for isolation and planarization. However, the step height of topography is still large.

Subsequently, to form the contact openings 14, 16, a photoresist layer (not shown) is patterned on the second dielectric layer 12. When conventional etching process is used to form the contact openings, it tends to result in either etch-stop or polymer-redeposit phenomena 18 on the dielectric layer 10, especially a silicon oxide layer. As shown in FIG. 2, the plurality of contact openings 14 is formed in the first dielectric and second dielectric layers 10 and 12. As mentioned above, when etching the second dielectric layer 12 and the first dielectric layer 10, the etch-stop or the polymer-redeposit phenomena 18 can be formed thereon. Thus the active regions are not exposed, thereby reducing the reliabilities of the contact openings.

Moreover, it also tends to over etch 20 the active regions or the silicon substrate when the conventional etching process is performed to form the contact openings 16 to expose the active regions. Particularly, the contact openings 16 have larger dimensions than the contact openings 14, the silicon loss 20 in the active region and the silicon substrate 2 can be serious. The cross sectional view of the semiconductor device processed with the etching step mentioned above is shown in FIG. 2, in which the semiconductor devices is failed because the reliabilities of the contact openings of the semiconductor devices are low.

Because it is very difficult to use the conventional etching process to form the contact openings with different depths and dimensions, the yield of the semiconductor device of high integration is low. As the integrity of a semiconductor device getting higher, the reliability of contact is more important, and the etching step is becoming more critical. Therefore, it is a need to providing a method of using an etch stop layer to improve contact reliability of the semiconductor device, particularly the high density memory devices.

### SUMMARY OF THE INVENTION

It is an object of this invention to form a contact opening to an active region of a metal oxide semiconductor field effect transistor (MOSFET) device.

It is another object of this invention to form a contact opening with improved contact reliability using an etch stop layer to exactly control main etching of the contact openings without unwanted overetch or etch-stop phenomena.

It is still another object of this invention to use an etch stop layer, allowing a first dry etching procedure to create the contact openings in a thick ILD layer, exposing the underlying etch stop layer, then using another dry etching procedure to complete the contact openings.

In accordance with the present invention a method for forming contacts of memory devices using an etch stop layer is described. A semiconductor substrate is provided having a plurality of memory devices, such as DRAM, SDRAM, flash, or embedded DRAM, and a plurality of isolation regions formed thereon. An undoped silicon oxide layer is formed on the plurality of memory devices, the plurality of isolation regions, and the semiconductor substrate for isolation. An etch stop layer, comprised of silicon nitride or silicon oxynitride, is formed on the undoped silicon oxide layer. The etch stop layer is also serve as a diffusion barrier. A thick interlevel dielectric layer, such as BPSG, is then deposited on the etch stop layer. A photoresist layer is pattern on the interlevel dielectric layer to define contact regions depending on design. A first dry etching process, such as selective RIE procedure, is performed to create a plurality of contact openings with different dimension in the thick interlevel dielectric layer until exposing portions of the etch stop layer. A second dry etching process is performed to create the plurality of contact openings through the etch stop layer. A third dry etching process is then performed to create the plurality of contact openings through the undoped silicon oxide layer, exposing portions of the active regions of the plurality of semiconductor devices. The pattern photoresist layer is removed. A conductive layer is filled in the plurality of contact openings to complete the contact structures.

### BRIEF DESCRIPTION OF THE DRAWINGS

The above features of the present invention will be more clearly understood from consideration of the following descriptions in connection with accompanying drawings in which:

FIG. 1 illustrates a cross sectional view of forming an interlevel dielectric layer on semiconductor substrate according to a conventional process;

FIG. 2 illustrates the cross sectional view of forming contact openings on the semiconductor substrate by conventional process;

FIG. 3 illustrates a cross sectional view of forming an isolation layer on the semiconductor substrate according to preferred embodiments of the present invention;

FIG. 4 illustrates a cross sectional view of forming an etch stop layer on the isolation layer of the semiconductor substrate according to preferred embodiments of the present invention;

FIG. 5 illustrates a cross sectional view of forming an planarization dielectric layer on the etch stop layer of the semiconductor substrate according to preferred embodiments of the present invention;

FIG. 6 illustrates a cross sectional view of performing a first etching step to create a plurality of contact openings to expose portions of the etch stop layer on the semiconductor substrate according to preferred embodiments of the present invention;

FIG. 7 illustrates a cross sectional view of performing a second etching step to create a plurality of contact openings through the etch stop layer on the semiconductor substrate according to preferred embodiments of the present invention; and

FIG. 8 illustrates a cross sectional view of performing a third etching step to create a plurality of contact openings on the semiconductor substrate according to preferred embodiments of the present invention.

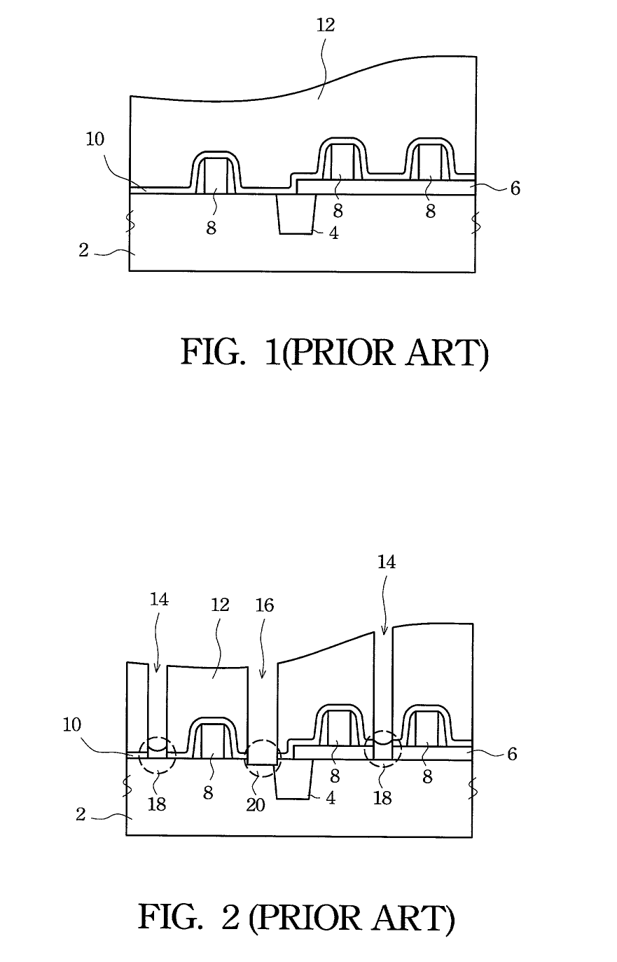

### DESCRIPTION OF THE PREFERRED EMBODIMENT

The present invention will be discussed in detail below with the reference to the drawings.

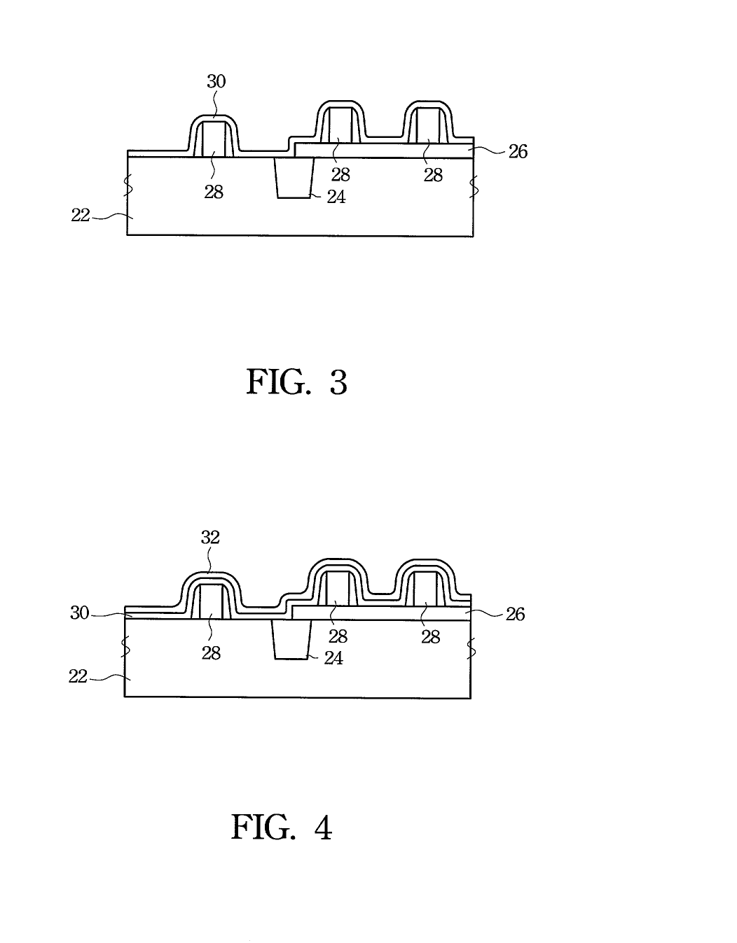

A single crystalline semiconductor substrate 22 is used and shown schematically in FIG. 3. A plurality of isolation regions 24, can be comprised of either a silicon oxide filled, shallow trench region, or a thermally grown, silicon dioxide, field oxide region, is next formed in the semiconductor substrate 22. A pad dielectric layer 26 is thermally grown or deposited by high density plasma CVD (HDP-CVD), at a thickness between about 500 to 2000 Angstroms. A plurality of semiconductor devices 28, comprised of a gate structure, dielectric spacers, active regions, and capacitor etc., is formed by conventional processes, such as deposition, etching, ion implantation, and photolithography etc. The semiconductor devices can be any types of memory devices, such as DRAM, SDRAM, Flash, or Embedded DRAM and so on. After formation of semiconductor devices, an isolation layer 30, such as undoped silicon oxide (USG) layer, is next deposited via LPCVD or plasma enhanced chemical vapor deposition (PECVD), at a thickness between about 500 to 1500 Angstroms.

A critical feature of this invention, the deposition of a thin insulator layer 32, to be used as an etch stop layer, during subsequent contact structures, is next addressed. Referring to FIG. 4, a silicon nitride or a silicon oxynitride layer 32, is used as the thin, insulator etch stop layer. Silicon oxynitride layer 32, will offer the etch rate selectivity needed during a dry etching procedure, such as reactive ion etching (RIE), used for the subsequent contact structures, and of upmost importance, can be serve as a diffusion barrier to improving the reliability issues of the semiconductor devices. Silicon oxynitride layer 32, shown schematically in FIG. 4, is deposited via chemical vapor deposition, such as LPCVD or PECVD, at a temperature between about 300 to 450° C., to a thickness between about 100 to 700 Angstroms. Similarly, silicon nitride layer 32 is deposited via low pressure chemical vapor deposition to a thickness between about 300 to 700 Angstroms.

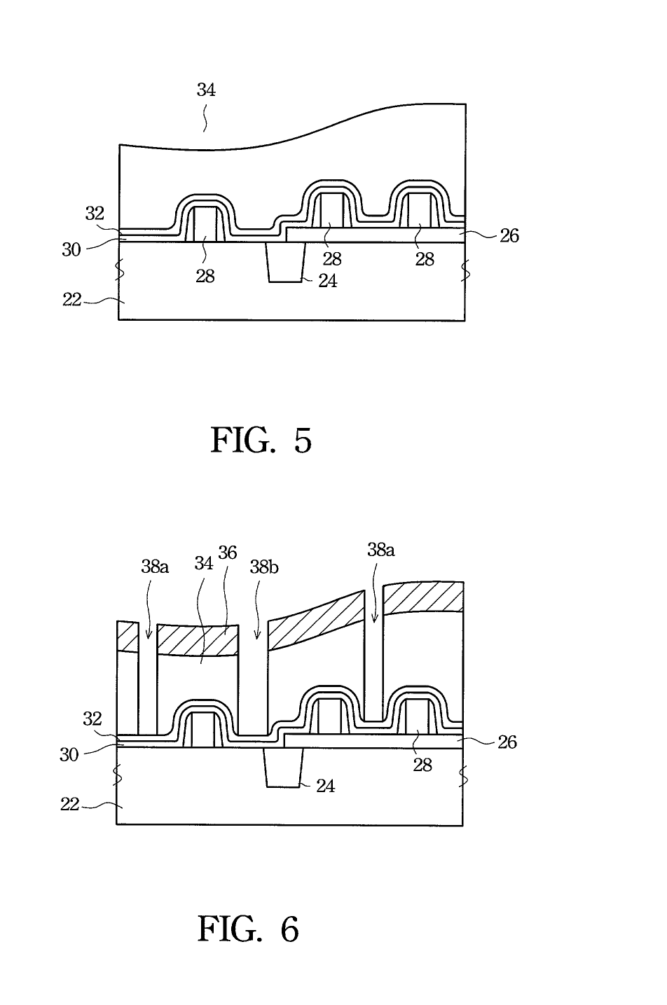

An interlevel dielectric (ILD) layer 34 also served as a planarization dielectric layer, comprised of silicon oxide, is next deposited via PECVD or LPCVD procedures on the etch stop layer 32, to a thickness between about 11000 to 16000 Angstroms. The ILD layer 34, shown schematically in FIG. 5, can also be comprised of borophosphosilicate glass (BPSG). The ILD layer 34 is then flowed at a temperature between about 750 to 850° C. with furnace or rapid thermal process (RTP). A chemical mechanical polishing (CMP) procedure may be then employed for planarization purposes, resulting in a smooth top surface topography for the ILD layer 34. The ILD layer is polished to a thickness of about 5000 to 7000 Angstroms

Next, referring to FIG. 6, a photoresist layer 36 is formed on the ILD layer 34 and then pattern to define the subsequent contact regions to be formed in the ILD layer 34, the etch stop layer 32 and in the isolation layer 30. A dry etching procedure, such as a selective RIE procedure, using C₄F₈/CO as an etchant, is used to remove portions of the ILD layer 34, exposed in the pattern photoresist layer 36, shown schematically in FIG. 5. In a preferred embodiment, an etch rate ratio of the ILD layer 34 (BPSG) to silicon oxynitride 32 is about 200, allowing this first phase of the RIE procedure, the etching of ILD layer 34, to be monitored by the appearance of the etch stop layer 32 comprised of silicon oxynitride. The depths of contact openings 38a, 38b in array region and periphery regions are different. The sizes of contact openings 38a, 38b in the ILD layer 34 are also different, such as a dimension of the contact opening 38a is smaller than the dimension of the contact opening 38b shown in FIG. 6. It tends to result in either the etch-stop or polymer redeposit in deep and small contact openings, and result in over-etch in shallow and large contact openings. However, the main etching of the ILD layer 34 to create the different depths and sizes contact openings can be initially controlled precisely according to the present invention.

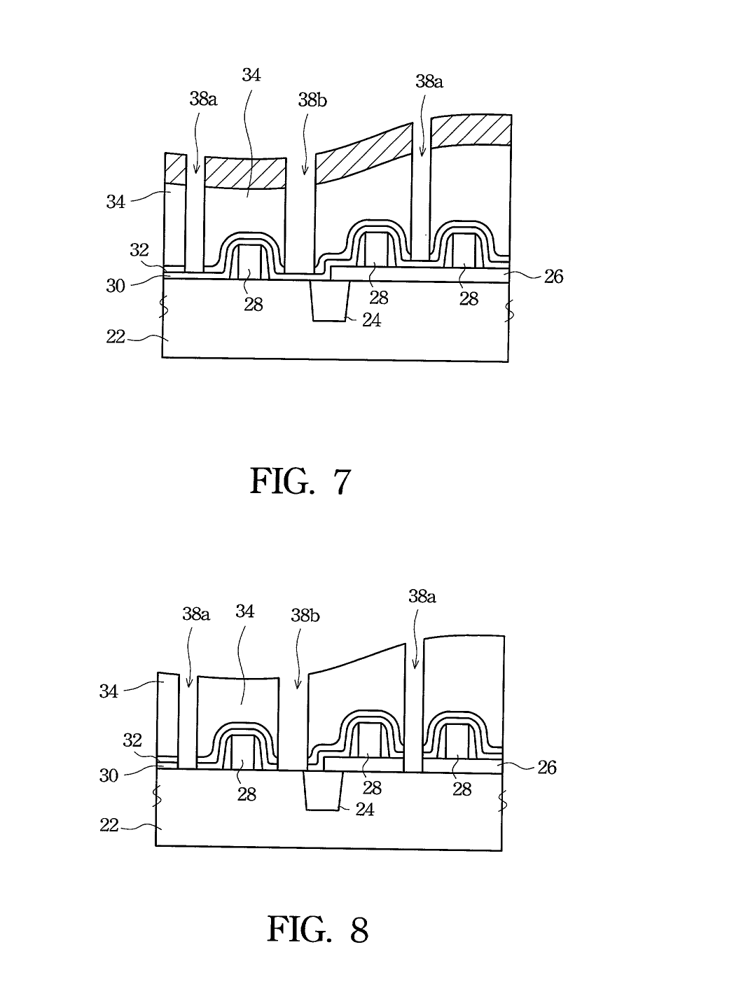

A second RIE phase, using CH₃F/O₂ as an etchant, is then used to selectively remove exposed regions of the silicon oxynitride layer 32, resulting in contact openings 38a, 38b, shown schematically in FIG. 7. In a preferred embodiment, an etch rate ratio of the silicon oxynitride 32 to the undoped silicon oxide layer 30 is about 10-20, allowing this second phase of the RIE procedure, the etching of etch stop layer 32, to be monitored by the appearance of the isolation dielectric layer 30 comprised of undoped silicon oxide. The endpoint for the second phase of RIE procedure can be initially controlled precisely.

A third RIE phase, using CHF₃ as an etchant, is then used to selectively remove exposed regions of the undoped silicon oxide layer 30 and the pad dielectric layer 26, resulting in contact openings 38a, 38b, shown schematically in FIG. 8. In a preferred embodiment, an etch rate ratio of the undoped silicon oxide layer 30 to the silicon substrate 22 is about 200, allowing this third phase of the RIE procedure, the etching of silicon oxide layer 30, to be monitored by the appearance of the silicon substrate 22. The endpoint for the third phase of RIE procedure can be initially controlled precisely. The three-step etching process of the present invention is performed via the etch stop characteristics of silicon oxynitride layer 32 allowed the different dimension contact openings 38a, 38b to be successfully formed without unwanted etch-stop of silicon oxide layer or overetch of the underlying active regions. Therefore, the contact reliability of the semiconductor devices can be apparently improved.

After removal of the pattern photoresist layer 36, used to define contact openings 38a, 38b, via plasma oxygen ashing and careful wet cleans, a conductive layer (not shown) is deposited, completely filling contact openings 38a. 38b. The conductive layer can be comprised of tungsten, aluminum, copper, or polysilicon. Regions of the conductive layer, residing on the top surface of the ILD layer 34, are then removed via a chemical mechanical polishing procedure, or via a selective RIE procedure to complete the contact structures.

As is understood by a person skilled in the art, the foregoing description of the preferred embodiment of the present invention is an illustration of the present invention rather than a limitation thereon. It is intended to cover various modifications and similar arrangements included within the spirit and scope of the appended claims. The scope of the claims should be accorded to the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. A method for forming contacts of semiconductor devices, said method comprising the steps of:
providing a semiconductor substrate having a plurality of device structures and a plurality of isolation regions formed thereon;
forming an isolation dielectric layer on said plurality of device structures, said plurality of isolation regions, and said semiconductor substrate;
forming an etch stop layer on said isolation dielectric layer;
forming an interlevel dielectric layer on said etch stop layer;
forming a photoresist pattern on said interlevel dielectric layer to define a plurality of contact regions;
performing a first etching process to create a plurality of contact openings with different dimension sizes in said interlevel dielectric layer until exposing portions of said etch stop layer;
performing a second etching process to create said plurality of contact openings with different dimension sizes through said etch stop layer until exposing portions of said isolation dielectric layer;
performing a third etching process to create said plurality of contact openings with different dimension sizes through said isolation dielectric layer, exposing portions of active region of said plurality of device structures;
removing said photoresist pattern layer; and
filling a conductive material in said plurality of contact openings to form a plurality of contacts for electrically connecting.

2. The method according to claim 1, wherein said plurality of device structures is a plurality of memory devices.

3. The method according to claim 2, wherein said memory device is a flash memory cell.

4. The method according to claim 1, wherein said isolation dielectric layer is an undoped silicon glass (USG).

5. The method according to claim 1, wherein said isolation dielectric layer has a thickness of about 500 to 1500 Å.

6. The method according to claim 1, wherein said etch stop layer is a silicon nitride layer.

7. The method according to claim 1, wherein said etch stop layer is a silicon oxynitride layer.

8. The method according to claim 1, wherein said etch stop layer has a thickness of about 100 to 700 Å.

9. The method according to claim 1, wherein said etch stop layer is also serve as a diffusion barrier.

10. The method according to claim 1, wherein said interlevel dielectric layer is a BPSG layer.

11. The method according to claim 1, wherein a depth of said plurality of contact openings is different from each other.

12. The method according to claim 1, wherein said first etching process is selective Reactive Ion Etching (RIE).

13. The method according to claim 1, wherein said first etching process is performed using C₄F₈/CO as an etchant.

14. The method according to claim 1, wherein an etch rate ratio of said interlevel dielectric layer to said etch stop layer in said first etching process is about 200.

15. The method according to claim 1, wherein said second etching process is selective Reactive Ion Etching (RIE).

16. The method according to claim 1, wherein said second etching process is performed using CH₃F/O₂ as an etchant.

17. The method according to claim 1, wherein an etch rate ratio of said etch stop layer to said isolation dielectric layer in said second etching process is about 10-20.

18. The method according to claim 1, wherein said third etching process is selective Reactive Ion Etching (RIE).

19. The method according to claim 1, wherein said third etching process is performed using CHF₃ as an etchant.

20. The method according to claim 1, wherein an etch rate ratio of said isolation dielectric layer to said semiconductor substrate in said third etching process is about 150-200.

21. A method for forming a plurality of contacts with different dimension sizes on a semiconductor substrate using an etch stop layer, said semiconductor substrate having a plurality of memory devices and a plurality of isolation regions formed thereon, said method comprising the steps of:
forming an undoped silicon oxide layer on said plurality of memory devices, said plurality of isolation regions, and said semiconductor substrate;
forming an etch stop layer on said undoped silicon oxide layer;
forming a BPSG layer on said etch stop layer;
forming a photoresist pattern on said BPSG layer to define a plurality of contact regions;
performing a first dry etching process to etch through said BPSG layer to create a plurality of contact openings until exposing portions of said etch stop layer;
performing a second dry etching process to create said plurality of contact openings through said etch stop layer until exposing portions of said undoped silicon oxide layer;
performing a third dry etching process to create said plurality of contact openings through said undoped silicon oxide layer, exposing portions of said semiconductor substrate and portions of active region of said plurality of device structures;
removing said photoresist pattern layer; and
filling a conductive material in said plurality of contact openings to form a plurality of contacts for electrically connecting.

22. The method according to claim 21, wherein said undoped silicon oxide layer has a thickness of about 500 to 1500 Å.

23. The method according to claim 21, wherein said etch stop layer is a silicon nitride layer.

24. The method according to claim 21, wherein said etch stop layer is a silicon oxynitride layer.

25. The method according to claim 21, wherein said etch stop layer has a thickness of about 100 to 700 Å.

26. The method according to claim 21, wherein said etch stop layer is serve as a diffusion barrier.

27. The method according to claim 21, wherein said first dry etching process is performed using C₄F₈/CO as an etchant.

28. The method according to claim 21, wherein an etch rate ratio of said BPSG layer to said etch stop layer in said first dry etching process is about 200.

29. The method according to claim 21, wherein said second dry etching process is performed using CH₃F/O₂ as an etchant.

30. The method according to claim 21, wherein an etch rate ratio of said etch stop layer to said undoped silicon oxide layer in said second dry etching process is about 10-20.

31. The method according to claim 21, wherein said third dry etching process is performed using CHF₃ as an etchant.

32. The method according to claim 21, wherein an etch rate ratio of said undoped silicon oxide layer to said semiconductor substrate in said third dry etching process is about 200.
